(19) United States
(12) Patent Application Publication
(10) Pub. No.: US 2007/0238281 A1
(43) Pub. Date: Oct. 11, 2007

(54) Depositing polar materials on non-polar semiconductor substrates

(76) Inventors: Mantu K. Hudait, Portland, OR (US); Mohamad A. Shaheen, Portland, OR (US); Loren A. Chow, Santa Clara, CA (US); Peter G. Tolchinsky, Beaverton, OR (US); Joel M. Fastenau, Bethlehem, PA (US); Dmitri Loubychev, Bethlehem, PA (US); Amy W.K. Liu, Mountain View, CA (US); Suman Datta, Beaverton, OR (US); Jack T. Kavalieros, Portland, OR (US); Robert S. Chau, Beaverton, OR (US)

Correspondence Address: TROP PRUNER & HU, PC, 1616 S. VOSS ROAD, SUITE 750, HOUSTON, TX, 77057-2631, US

(21) Appl. No.: 11/391,510

(22) Filed: Mar. 28, 2006

(51) Int. Cl. H01L 21/28

(52) U.S. Cl. 438/604

(57) ABSTRACT

Lattice mismatch and polar to non-polar issues may lead to dislocations and other defects between silicon or germanium substrates and group III-V materials such as indium antimonide. The provision of lattice matching layers and buffer layers may enable these defects to be reduced.

### BACKGROUND

This invention relates generally to the fabrication of integrated circuits.

In many complementary metal oxide semiconductor (CMOS) logic operations it is desirable to have high mobility material for both NMOS and PMOS transistors. With silicon (Si) substrates, low electron or hole mobility values limit speed and increase power consumption. On the other hand, growing high electron and hole mobility materials, such as indium antimonide (InSb), on a silicon or germanium (Ge) substrates, greatly improves logic performance.

Integrating these two systems onto a single semiconductor substrate is challenging. The group III-V materials, in general, have high electron mobility compared to silicon. However, the group III-V materials are not amenable to being deposited onto silicon or other substrates.

There are several reasons for this. There may be a lattice mismatch between the group III-V material and the starting substrate. In addition, the group III-V material may be polar, while the substrate may be non-polar. A non-polar material is completely covalently bonded while a polar material is not completely covalently bonded. These incompatibilities result in defects that are detrimental to material quality, electrical properties, and, hence, device usefulness when group III-V layers grown on silicon or germanium.

### BRIEF DESCRIPTION OF THE DRAWINGS

FIG. 1 is a depiction of a structure on a germanium substrate in accordance with one embodiment of the present invention;

FIG. 2 is a depiction of a structure on a germanium substrate in accordance with another embodiment of the present invention;

FIG. 3 is a graph of bandgap versus lattice constant for group III-V materials;

FIG. 4 is a depiction of a structure in accordance with one embodiment of the present invention on a silicon substrate; and

FIG. 5 is a schematic, atomic level view of an interface between a silicon substrate and a lattice matched layer as depicted in FIG. 4 in accordance with one embodiment of the present invention.

### DETAILED DESCRIPTION

By monolithic integration of group III-V materials on silicon or germanium substrates, the substrate surface lattice constant need not change prior to growth of large lattice mismatch materials onto the substrate. Examples of large lattice mismatch materials, relative to silicon or germanium, include gallium arsenide (GaAs), indium phosphide (InP), aluminium antimonide (AlSb), and indium antimonide (InSb).

The problem of polar materials being grown on a non-polar interface, like silicon or germanium, may be addressed by growing near lattice match group III-V material with a mismatch less than 0.3% onto a germanium substrate. This can reduce the large mismatch problem compared to growing group III-V material directly onto silicon or germanium.

In some embodiments of the present invention, polar-on-non-polar-mismatch and lattice mismatch may be addressed by decoupling the two issues. First, a polar group III-V material is used subsequently to grow a lattice mismatch, but equally polar group III-V device layer.

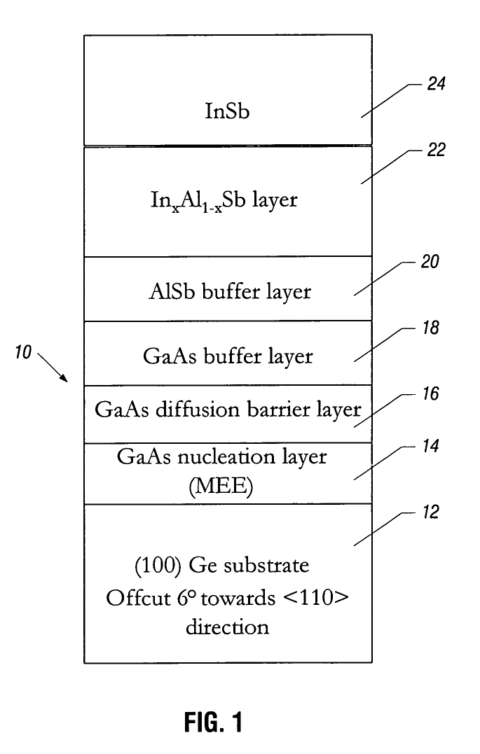

Referring to FIG. 1, it may be desirable to form a group III-V material, such as InSb layer 24, over a germanium substrate 12. However, because of the polar nature of the layer 24 versus the non-polar nature of the substrate 12, it may be difficult to apply the layer 24 directly on the substrate 12 without defects. Also, there is a lattice mismatch between the layer 24 and the substrate 12. More particularly, growing polar group III-V material on the non-polar germanium substrates may result in anti-phase domains.

The germanium substrate 12 may be a [100] germanium material off cut at 2 to 9 degrees, for example 6 degrees, towards the [110] direction. Migration enhanced epitaxy (MEE) may be used to develop an anti-phase domain free, gallium arsenide such as nucleation layer 14. A molecular beam epitaxy (MBE) system “GEN-III” available from Veeco Instruments, Inc., St. Paul, Minn., is suitable for growing the materials. Any epitaxial growth technique, e.g., atomic layer epitaxy, chemical beam epitaxy, metal-organic vapor-phase epitaxy, metal-organic molecular beam epitaxy can also be used for this purpose. The layer 14 may be chosen to be a group III-V material with a lattice constant not more than 5% larger than germanium.

The off cutting of the substrate creates a stepped surface. Then, a monolayer of arsenic may be grown. After a period of time, such as one minute, a layer of gallium is grown on the just formed layer of arsenic. Gallium controls the growth rate of gallium arsenide. After a comparable delay period, the sequence may be repeated, for example, 40 to 50 times. As a result, the formation of anti-phase boundaries may be inhibited.

The nucleation layer may, for example, be from 50 to 300 Angstroms. A low flux rate (e.g., 6×10⁻⁷ Torr), slow growth rate (e.g., 0.1 μm/hr), and a low temperature (e.g., 400° C.) may be used in some embodiments. At this point, a polar surface layer has been achieved that may be free of anti-phase boundaries.

Then, a mixed arsenic and antimony based buffer architecture is deposited, as indicated by the gallium arsenide diffusion barrier layer 16 and the gallium arsenide buffer layer 18. A low defect density indium antimonide film 24 may be grown on 6 degree offset germanium substrates using the gallium arsenide buffer layer 18, an aluminium antimonide buffer layer 20, and a gallium arsenide, aluminium antimonide, or indium aluminium antimonide (InAlSb) buffer layer 22.

The barrier layer 16 may be more crystalline, having been grown at a higher temperature (e.g., 600° C.) again using the same equipment. However, the alternating flows of arsenic and gallium need not be used in some cases. The layer 16 prevents diffusion of dopants downwardly into the nucleation layer 14 or the germanium substrate 12. In one embodiment, the diffusion barrier may be 0.1 micron thick.

The buffer layer 18 may be one to two microns thick, in one embodiment, and may be formed at about 600° C. The buffer layer 18, if made of gallium arsenide, may have a lattice mismatch with indium antimonide.

In some embodiments, that mismatch may be addressed by using an intervening layer 20, such as aluminium antimonide, with a smaller (e.g., 9%) mismatch. Fortunately, dislocations do not propagate into this layer. It should be noted that, on the other side, gallium arsenide very nicely matches the germanium lattice constant.

Next, another intervening layer may be used in some cases. For example, the layer 22 of the InₓA₁₋ₓSb layer 22 may be used where x gradually goes from zero to one, from the bottom to the top, of the layer 22. The layer 22 may be a barrier layer for the device layer. All of the layers may be formed by MBE in some embodiments.

Finally, indium antimonide is grown on the underlying layer 22 to form the layer 24. As an example, the layer 24 may be two microns thick.

In some embodiments, a buffer layer is formed to bridge the lattice mismatch gap between the overlayer group III-V compounds that is equally polar as the buffer group III-V compounds. Thus, in some embodiments, monolithic integration of any group III-V material on germanium may be achieved. This enables integration of high mobility, low bandgap material, such as indium antimonide, on germanium for low power, high speed logic applications. Moreover, it enables combining functionalities of group III-V devices, such as optical sensors, on silicon or germanium based logic.

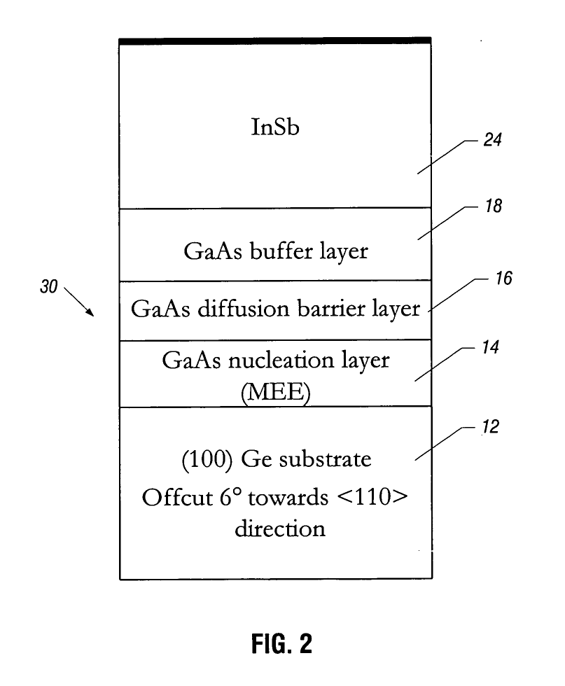

As another embodiment, shown in FIG. 2, a gallium arsenide nucleation layer 14 and a gallium arsenide diffusion barrier layer 16 may be covered by a gallium arsenide buffer layer 18, followed by indium antimonide layer 24a. The layer 24a may be thicker than the layer 24. For example, the layer 24 may be five microns.

The layers 20 and 22 may be dispensed with by carefully controlling the growth of the indium antimonide layer 24a to avoid threading dislocations. For example, the proper nucleation, growth rate, pressure, flux, and temperature may be controlled. Since dislocation glide is a thermally activated process, growing film at higher temperature leads to less dislocation present inside the film. Also, slow growth rate helps in proper site selection of growth species and glide of dislocation due to much longer residence time of growth species on the surface.

In some embodiments, high mobility and low defect density may be achieved in indium antimonide thin films grown on germanium wafers for CMOS logic applications. The mobility may be greater than 64,000 cm²/Vs at 2 μm InSb film (i.e., comparable to a bulk layer) and a defect density may be less than 5×10⁶ cm⁻², in some embodiments, with InSb films 24a grown on three inch germanium substrates for high mobility CMOS logic applications.

High mobility InSb integration onto an off-oriented germanium substrate may be achieved by selecting the proper germanium substrate orientation and the proper buffer architecture, which achieve the high mobility and low defect density InSb thin film. In this monolithic integration of InSb material on germanium, the surface lattice constant of the germanium substrate is not changed prior to large mismatch growth onto it.

The polar-on-nonpolar problem is addressed by growing lattice-match GaAs material (mismatch less than 0.1%) onto germanium substrate to address the extra problem associated with the large mismatch involved during III-V growth onto germanium. Dislocation density may be controlled by selecting the proper buffer design and the controlled nucleation and glide of dislocations.

In some cases, the embodiment of FIG. 2 may be used in non-device areas while the embodiments in FIG. 1 may be used in device areas. In some cases, germanium may be used for PMOS transistors and indium antimonide may be used for NMOS transistors. Other group III-V materials may be grown on germanium for the same purposes, such as indium arsenide (InAs) or high indium composition in indium gallium arsenide (InGaAs) channel layers.

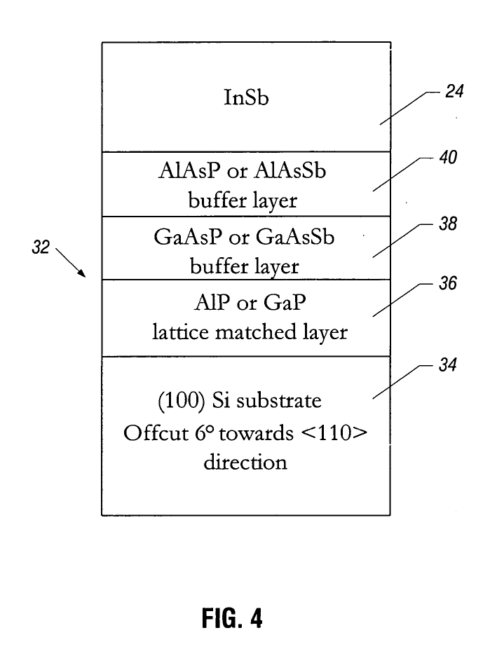

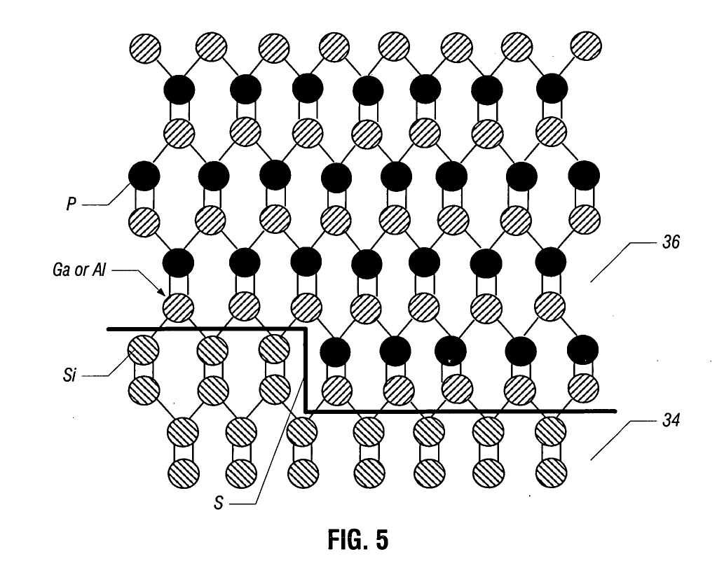

Referring next to FIG. 4, another semiconductor structure may have a group III-V material formed on a silicon substrate 34. The silicon substrate 34 may be [100] silicon off cut 6 degrees towards the [110] direction. The effect is illustrated by the step S in FIG. 5.

Then, a first lattice matched layer 36 may be grown on the silicon substrate 34. The layer 36 may, for example, be aluminium phosphide (AlP) or gallium phosphide (GaP). The layer 36 decouples the polar-on-non-polar issue from one lattice mismatch issue, forming a “virtual” polar silicon substrate.

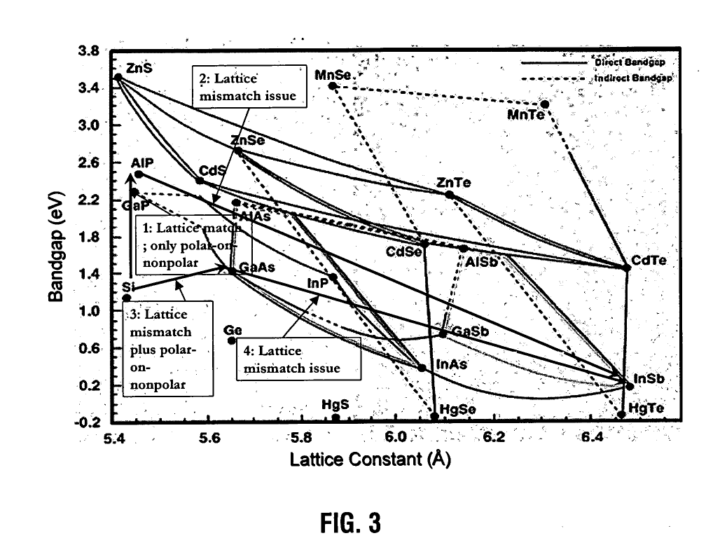

The particular material used may be selected from a graph of bandgap versus lattice constant (FIG. 3). Suitable materials for the layer 36 have similar lattice constants to silicon, but higher bandgaps. In some embodiments, the mismatch may be less than 5% and less than 0.3% in one embodiment.

Thereafter, a graded buffer layer 38 may be formed on the layer 36. The layer 38 may, for example, by gallium arsenide phosphide (GaAsP) or gallium arsenide antimonide (GaAsSb). Next, an aluminium arsenide phosphide (AlAsP) or aluminium arsenide antimonide (AlAsSb) buffer layer or other metamorphic buffer layer 40 is grown, followed by the indium antimonide layer 24.

To demonstrate this principle, GaAs was grown on a lattice matched (<0.1%) but non-polar germanium substrate, where lattice mismatch is decoupled from polar-on-nonpolar substrate issues. The dislocation density may be below the bulk material defect density (<5×10⁴ cm⁻²) in some embodiments.

In one embodiment, gallium phosphide (GaP) may be grown slowly and carefully by molecular beam epitaxy or metal organic chemical vapor deposition. Progressively, arsenic is substituted for phosphorous until gallium arsenide (GaAs) is being grown. As usual, the group III element controls the growth rate of the group III-V compounds.

Gallium phosphide (GaP) has a very small lattice mismatch with silicon. This overcomes the lattice mismatch problem, initially. The gradual substitution of phosphorous by arsenic formed gallium arsenide (GaAs)and gradual substitution of arsenic by antimony formed gallium antimonide (GaSb) and ultimately serves to match the final indium group III-V compound.

In another embodiment, aluminium phosphide (AlP) may be grown, followed by aluminium arsenide (AlAs) and the aluminium arsenide antimonide (AlAsSb).

One can progress along the FIG. 3 graph, first moving substantially vertically to avoid a large mismatch with silicon. This sequence overcomes the polar or non-polar issue. Then, gradually moving to the right, the mismatch to the final layer is overcome.

In still another embodiment, indium phosphide (InP) may be grown on germanium. Gallium arsenide is grown initially to match the lattice constant of germanium while forming a virtual polar germanium substrate. From here, antimony is gradually substituted for arsenic, forming gallium antimonide (GaSb). Thereafter, indium antimonide may be grown on the metamorphic buffer of gallium arsenide.

In some embodiments, the standard orientation [100] silicon may be used, but in other embodiments [211] and [511] may be utilized. The first lattice match layer 36 decouples polar on non-polar issues from lattice mismatch issues, forming a virtual polar silicon substrate. A degraded buffer architecture uses the layers 40 and 38 where only two group-V elements are substituted at a fixed growth rate in order to change the lattice constant through the buffer structure and bridge a span of lattice constants between the virtual polar substrate and the final layer, such as indium antimonide.

In some embodiments, high mobility group III-V materials may be formed on silicon substrates for CMOS logic applications. The polar on non-polar issue is decoupled from lattice mismatch for materials integration of large mismatch materials on silicon substrates. A reduction in dislocation density may be achieved in some cases, as well as the reduction of anti-phase domains resulting in high mobility group III-V layers.

The polar group III-V materials, such as aluminium phosphide or gallium phosphide, are closely lattice matched with silicon substrates and are grown on silicon substrates to create a virtual polar substrate for integrating larger mismatch materials. In this way, the polar issue can be decoupled from the lattice mismatch problem. Once a polar virtual substrate has been formed on the silicon structure, a metamorphic buffer utilizing either aluminium phosphide, aluminium arsenide, and aluminium antimonide or gallium phosphide, gallium arsenide, and gallium antimonide, can handle the larger lattice mismatch problem for indium antimonide on silicon substrates. The growth rate of each buffer material can be controlled by either aluminium for aluminium phosphide, aluminium arsenide, aluminium antimonide case or gallium for the gallium phosphide, gallium arsenide, gallium antimonide case. The lattice parameter, and hence the strain, will be controlled by mixing two group-V materials in these metamorphic buffers. One can control the lattice mismatch up to 15% on silicon substrates. Using this strategy, one can grow high quality indium antimonide on silicon substrates.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations there from. It is intended that the appended claims cover all such modifications and variations as fall within the true spirit and scope of this present invention.

What is claimed is:

1. A method comprising:
growing an indium containing group III-V compound over germanium.

2. The method of claim 1 including growing a polar layer over said germanium and forming said group III-V compound over that layer.

3. The method of claim 1 including growing a polar layer whose lattice constant is not more than 5% different than germanium.

4. The method of claim 1 including forming a nucleation layer over the germanium by alternatively growing monolayers of the group III and group-V materials.

5. The method of claim 4 including using epitaxial growth to form said monolayers.

6. The method of claim 5 including growing layers of two different group III-V compounds over the germanium.

7. The method of claim 6 wherein the first group III-V compound more closely matches the lattice constant of germanium and the second group III-V compound more closely matches the lattice constant of the indium compound.

8. The method of claim 7 including growing a first group III-V compound including gallium and growing a second group III-V compound over said first group III-V compound, said second group III-V compound including aluminium.

9. The method of claim 1 including growing indium antimonide directly on a gallium containing compound.

10. The method of claim 9 including growing indium antimonide directly on gallium arsenide.

11. A semiconductor structure comprising:
a germanium substrate; and
an indium group III-V compound over said germanium substrate.

12. The structure of claim 11 including a first layer on the germanium substrate with a lattice constant less than 5% different than the lattice constant of germanium.

13. The structure of claim 12 wherein said first layer includes alternating monolayers of a polar group III-V compound.

14. The structure of claim 13 including a second layer over said first layer and under said indium group III-V compound, said second layer having a lattice constant that is closer to that of the indium group III-V compound than said first layer.

15. The structure of claim 14 wherein said group III-V compound is indium antimonide, said first layer is gallium arsenide and said second layer includes aluminium antimonide.

16. A method comprising:
growing a group III-V first compound on a semiconductor substrate, said first compound having substantially the same lattice constant as said substrate and a higher bandgap than said substrate; and
growing a group III-V second compound on said substrate by gradually replacing the group V element of said first compound with a second group V element to form a compound having a substantially different lattice constant than said substrate; and
growing an indium group III-V compound over said second compound.

17. The method of claim 16 including using epitaxial growth to form said second compound.

18. The method of claim 16 including growing indium antimonide over germanium.

19. The method of claim 16 including growing indium antimonide over silicon.

20. The method of claim 19 including forming a third group III-V compound between said indium group III-V compound and said second compound.

21. A semiconductor structure comprising:
a semiconductor structure;
a group III-V first compound over said structure, said first compound lattice matched to said structure;
a group III-V second compound over said first compound which gradually transitions from said first compound to a second group III-V compound having a substantially different lattice constant than said first compound; and
an indium containing group III-V compound over said second compound.

22. The structure of claim 21 wherein said substrate is germanium.

23. The structure of claim 21 wherein said substrate is silicon.

24. The structure of claim 23 wherein said indium containing compound is indium antimonide.

25. The structure of claim 24 wherein said first compound includes gallium or aluminium.

26. The structure of claim 25 wherein said first compound includes phosphorous or arsenic.
